(19) United States
(12) Patent Application Publication
(10) Pub. No.: US 2017/0104903 A1
(43) Pub. Date: Apr. 13, 2017

(54) IMAGING DEVICE AND ELECTRONIC APPARATUS

(71) Applicant: SONY CORPORATION, TOKYO (JP)

(72) Inventors: TAKASHI WARASHINA, KUMAMOTO (JP); YASUHIRO SATO, KUMAMOTO (JP)

(21) Appl. No.: 15/316,928

(22) PCT Filed: Jun. 16, 2015
(86) PCT No.: PCT/JP2015/067230

§ 371 Date: Dec. 7, 2016

(30) Foreign Application Priority Data
Jun. 27, 2014 (JP) 2014-132763

(51) Int. Cl. H04N 5/225; G02B 13/00; G02B 7/02; H04N 5/33

(52) U.S. Cl. CPC H04N 5/2254; H04N 5/33; H04N 5/2253; G02B 13/0085; G02B 13/0055; G02B 7/021; G02B 5/208

(57) ABSTRACT

The present technology relates to an imaging device, and an electronic apparatus that contribute to downsize a module. A substrate to which an image sensor is mounted, a frame that fixes a lens, and the lens are included. The substrate, the frame, and the lens seals the image sensor. There are provided a plurality of lenses, and the lens fixed to the frame is a lens positioned nearest to the image sensor among a plurality of lenses. There may be further provided a lens barrel that holds the lenses, and the lenses other than the lens are positioned near the image sensor among the plurality of lenses are held by the lens barrel. The present technology is applicable to the imaging device.

### CROSS REFERENCE TO RELATED APPLICATIONS

This application is a U.S. National Phase of International Patent Application No. PCT/JP2015/067230 filed on Jun. 16, 2015, which claims priority benefit of Japanese Patent Application No. JP 2014-132763 filed in the Japan Patent Office on Jun. 27, 2014. Each of the above-referenced applications is hereby incorporated herein by reference in its entirety.

### TECHNICAL FIELD

The present technology relates to an imaging device, and an electronic apparatus, and in particularly to an imaging device, and an electronic apparatus that contribute to downsize a module.

### BACKGROUND ART

In recent years, along with downsizing of a digital camera and a wide spread of a mobile phone having a digital camera function, downsizing of a drive assembly for autofocusing is also desirable. Patent Document 1 suggests that downsizing is realized by sealing a lens holder, a chip, and a substrate.
Patent Document 1: Translation of PCT International Application Publication No. 2007-523568

### SUMMARY

### Problem to be Solved

It is possible to realize downsizing of an imaging device by downsizing an optical system such as a lens. However, it is a high possibility that unfavorable statuses such as a decreased amount of light and a poor image quality may be generated. Accordingly, it is unfavorable to downsize the imaging device by downsizing the lens or the like. However, as described above, it is desirable to further downsize the imaging device.

The present technology is made in view of such circumstances, and it is to realize further downsizing of the imaging device.

### Means for Solving the Problem

An imaging device according to an aspect of the present technology includes a substrate to which an image sensor is mounted; a frame that fixes a lens; and the lens, the substrate, the frame, and the lens sealing the image sensor.

There may be provided a plurality of lenses, and the lens fixed to the frame is a lens positioned nearest to the image sensor among a plurality of lenses.

There may be further provided a plurality of lenses; and a lens barrel that holds the lenses, and the lenses other than the lens are positioned near the image sensor among the plurality of lenses are held by the lens barrel.

A diameter of the lens barrel may be smaller than a diameter of the lens fixed to the frame.

There may be further provided an IRCF (Infra Red Cut Filter) on the image sensor.

The lens may have a function to cut infrared rays.

There may be further provided an IRCF (Infra Red Cut Filter).

There may be provided a plurality of lenses, and the lenses other than the lenses positioned at a frontmost surface and an endmost surface among the plurality of lenses move upon focusing.

An electronic apparatus according to an aspect of the present technology includes an imaging device including a substrate to which an image sensor is mounted, a frame that fixes a lens, and the lens, the substrate, the frame, and the lens sealing the image sensor; and a signal processing unit that performs signal processing to a signal output from the imaging device.

An imaging device according to an aspect of the present technology includes a substrate to which an image sensor is mounted; a frame that fixes a lens; and the lens, the substrate, the frame, and the lens sealing the image sensor.

According to an aspect of the present technology, the imaging device can be downsized.

It should be noted that the effect described here is not necessarily limitative and may be any effect described in the present disclosure.

### BRIEF DESCRIPTION OF DRAWINGS

FIG. 1 is a view showing a configuration of a camera module.

FIG. 2 is a view showing a configuration of a downsized camera module.

FIG. 3 is a view for explaining downsizing.

FIG. 4 is a view showing other configuration of a downsized camera module.

FIG. 5 shows a configuration of an electronic apparatus.

### DESCRIPTION OF PREFERRED EMBODIMENTS

Hereinafter, modes for carrying out the present technology (hereinafter referred to as embodiments) will be described referring to drawings.

The description will be made in the following order.

1. Configuration of Imaging device
2. Configuration of Downsized Imaging device
3. Other Configuration of Downsized Imaging device

### 4. Electronic Apparatus

<Configuration of Imaging Device>

The present technology is applicable to a camera module including an image sensor for focus adjustment. The camera module to which the present technology is applied can be more downsized as compared with the camera module in the related art. To clearly explain the downsizing of the camera module, the camera module (imaging device) in the related art is firstly explained.

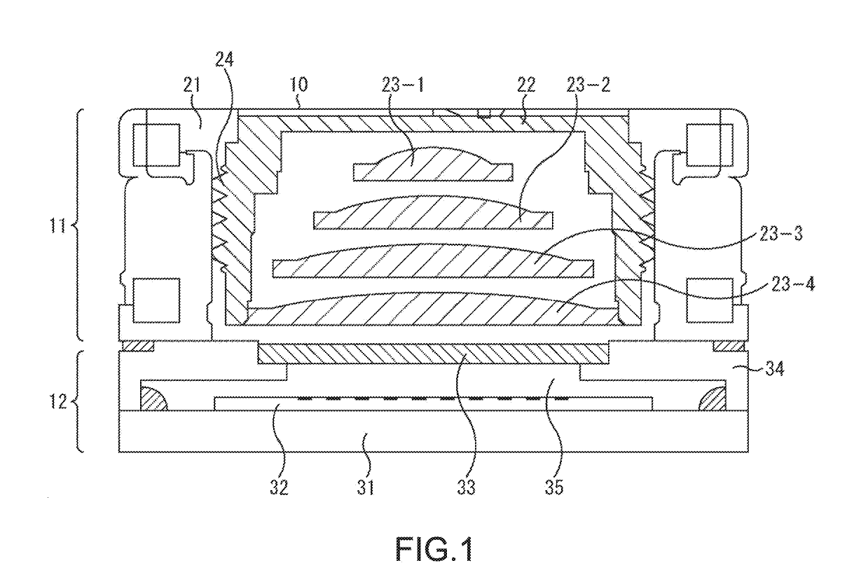

FIG. 1 is a cross-sectional view showing a configuration of an imaging device. An imaging device 10 shown in FIG. 1 is configured of an upper part 11 and a lower part 12. Here, for convenience of the explanation, the imaging device 10 is configured of the upper part 11 and the lower part 12.

The upper part 11 is configured of an actuator 21, a lens barrel 22, and a lens 23. The lower part 12 is configured of a substrate 31, an image sensor 32, an IRCF (Infra Red Cut Filter) 33, and a frame 34.

Four lenses of lens 23-1, lens 23-2, lens 23-3, and lens 23-4 are incorporated within the lens barrel 22, and the lens barrel 22 is configured to hold the lenses 23-1 to 23-4. The lens barrel 22 is included in the actuator 21, and the lower part 12 is mounted to a bottom of the actuator 21.

For example, a screw 24 is provided at an outer side surface of the lens barrel 22. A screw (not shown) is provided at a part of inside of the actuator 21 at a position where the screw and the screw 24 are engaged. The screw 24 of the lens barrel 22 and the screw inside of the actuator 21 are configured to be engaged.

When it is configured to move the lens barrel 22 in an up-and-down direction in the figure and to perform an autofocus (AF), a coil is provided at a side surface of the lens barrel 122 (lens carrier to which the lens barrel 122 is mounted). A magnet is provide at a position opposing to the coil and within the actuator 21. The magnet has a yoke, and the coil, the magnet and the yoke configure a voice coil motor.

Once a current flows the coil, a force is generated in the up-and-down direction in the figure. The generated force moves the lens barrel 22 in the up direction or the down direction. By moving the lens barrel 22, a distance between the lens 23-1 to 23-4 held by the lens barrel 22 and the image sensor 32 is changed. Such a mechanism can realize the autofocus.

As a center of the lower part 12, the image sensor 32 is provided. The image sensor 32 is mounted onto the substrate 31, and is connected to the substrate 31 by wiring (not shown). The frame 34 is mounted onto the surface of the substrate 31 on which the image sensor 32 is provided. The frame 34 has a function to hold an IRCF 33. The upper part 11 is provided at the frame 34 opposite to surface with which the substrate 31 is contacted.

The substrate 31, the IRCF 33, and the frame 34 are intimately adhered with no clearance so that foreign matters such as particles do not enter into a space 35 surrounded by the substrate 31, the IRCF 33, and the frame 34. The space 35 is an almost hermetically sealed space by the substrate 31, the IRCF 33, and the frame 34.

In this way, the space 35 is configured such that the foreign matters does not enter. The IRCF 33 functions as a filter for cutting infrared rays, and is used for sealing the image sensor 32 into the space 35, too.

<Configuration of Downsized Imaging Device>

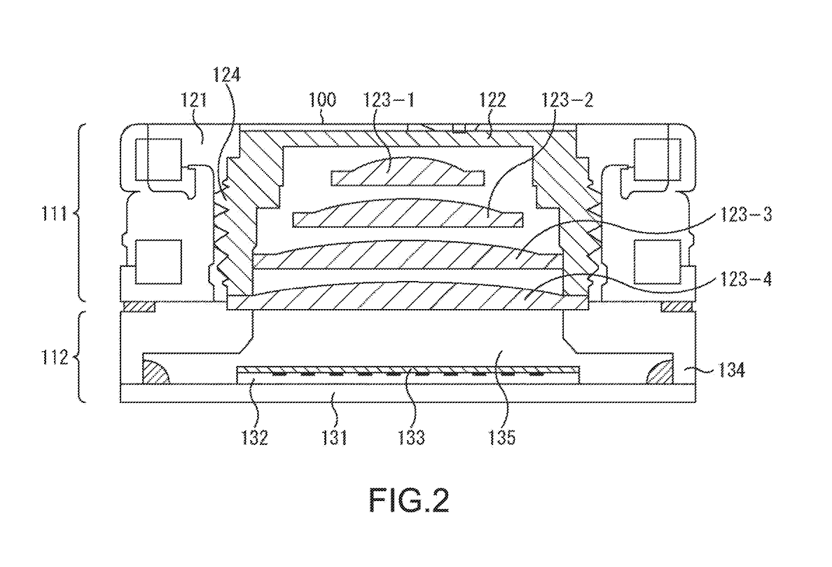

FIG. 2 shows a configuration of a downsized imaging device according to an embodiment smaller than the imaging device shown in FIG. 1. An imaging device 100 shown in FIG. 2 basically includes the same components as those of the imaging device 10 shown in FIG. 1, but their arrangement is different.

The imaging device 100 shown in FIG. 2 is configured of an upper part 111 and a lower part 112. Also in FIG. 2, for convenience of the explanation, the imaging device 100 is configured of the upper part 111 and the lower part 112.

The upper part 111 includes an actuator 121, a lens barrel 122, and lenses 123-1 to 123-3. The lower part 112 includes a substrate 131, an image sensor 132, an IRCF 133, a frame 134, and a lens 123-4.

Three lenses of the lens 123-1, the lens 123-2, and the lens 123-3 are incorporated within the lens barrel 122, and the lens barrel 122 is configured to hold the lenses 123-1 to 123-3. The lens barrel 122 is included in the actuator 121, and the lower part 112 is mounted to a bottom of the actuator 121.

Although the lens 23-4 of the imaging device 10 shown in FIG. 1 is included in the upper part 11, the lens 123-4 of the imaging device 100 shown in FIG. 2 is included in the lower part 112. The lens 23-4 and the lens 123-4 are positioned near the image sensor 32 (132) among the plurality of the lenses included in the imaging device 10 (100). Here, the lens positioned nearest to the image sensor 32 (132) is described as a final ball, as appropriate.

In the imaging device 100 shown in FIG. 2, the final ball among the lenses configuring a lens group is not included in the lens barrel 122, and is fixed to the frame 134.

Also in the imaging device 100, a screw 124 is provided at an outer side surface of the lens barrel 122. A screw (not shown) is provided at a part of inside of the actuator 121 at a position where the screw and the screw 124 are engaged. The screw 124 of the lens barrel 122 and the screw inside of the actuator 21 are configured to be engaged.

When it is configured to engage the lens barrel 122 with the actuator 121, a distance from the image sensor 132 can be matched (focused) upon manufacturing. The above-described way to mount the lens barrel 122 to the actuator 121 is illustrative. The lens barrel 122 may be mounted to the actuator 121 by other mechanism.

When it is configured to move the lens barrel 122 in an up-and-down direction in the figure and to perform an autofocus (AF), a coil is provided at a side surface of the lens barrel 122 (lens carrier to which the lens barrel 122 is mounted). A magnet is provide at a position opposing to the coil and within the actuator 121. The magnet has a yoke, and the coil, the magnet and the yoke configure a voice coil motor.

Once a current flows the coil, a force is generated in the up-and-down direction in the figure. The generated force moves the lens barrel 122 in the up direction or the down direction. By moving the lens barrel 122, a distance between the lens 123-1 to 123-4 held by the lens barrel 122 and the image sensor 132 is changed. Such a mechanism can realize the autofocus.

Note that other mechanism may be used to realize the autofocus, and the configuration is corresponded to the way to realize. For example, a wire formed of a shape memory alloy may be used to move the lens barrel 122 in the up-and-down direction.

In the imaging device 100, the lens barrel 122 includes the three lenses of the lenses 123-1 to 123-3. In the imaging device 10 shown in FIG. 1, the lens barrel 22 includes the four lenses of the lenses 23-1 to 23-4. When the imaging device 10 is compared with the imaging device 100, the number of the lenses included in the lens barrel 122 of the imaging device 100 is lower than the number of the lenses included in the lens barrel 22 of the imaging device 10.

Accordingly, the lens barrel 122 of the imaging device 100 has a weight at least lower than that of the lens barrel 22 of the imaging device 10 as to the lens that is the final ball. As described later, the lens barrel 122 can be smaller than the lens barrel 22, thereby saving the weight of the lens barrel 122 itself.

As the lens barrel 122 has a light weight, it is possible to decrease a force to drive the lens barrel 122. Accordingly, when it is configured that the force to drive the lens barrel 122 is generated using the coil, etc. as described above, the current for flowing the coil can be decreased. In other words, by applying the present technology, a power consumption can be decreased.

Turning back to the description about the imaging device 100 shown in FIG. 2, at a center of the lower part 112, the image sensor 132 is provided. The image sensor 132 is mounted onto the substrate 131, and is connected to the substrate 131 by wiring (not shown). The IRCF 133 is provided at a lens 123-4 side of the image sensor 132.

The frame 134 is mounted onto the surface of the substrate 131 on which the image sensor 132 is provided. The frame 134 has a function to hold the lens 123-4. The upper part 111 is provided at the frame 134 opposite to surface with which the substrate 131 is contacted.

The lens 123-4, the substrate 131, and the frame 134 are intimately adhered with no clearance so that foreign matters such as particles do not enter into a space 135 surrounded by the lens 123-4, the substrate 131, and the frame 134. The space 135 is an almost hermetically sealed space by lens 123-4, the substrate 131, and the frame 134.

In this way, the space 135 is configured such that the foreign matters do not enter. The lens 123-4 functions as a lens for collecting light, and is used for sealing the image sensor 133 into the space 135, too.

The space 135 may be configured of a hermetically sealed space fully sealed using an adhesive agent or the like, or may be a space where air can be entered or exited more or less by an air intake and exhaust path, etc.

For example, when the manufacturing process includes the step of escaping thermally-expanded air from the space 135, a vent to escape the air is provided. After the thermally-expanded air is escaped from the vent, the vent may be left as it is. Alternatively, there is provided an additional step to block the vent with an adhesive agent so as not to leave the vent.

When the air intake and exhaust path such as the vent is provided, the size of the air intake and exhaust path is set not to enter foreign matters that invade the space 135, attach to the image sensor 132, and affect the imaging. With this size, it prevents the foreign matters from entering into the space 135 and adversely affecting, thereby acquiring the similar effects as a hermetically sealed state.

Here, the almost hermetically sealed space includes a structure having the air intake and exhaust path and a structure having no air intake and exhaust path (structure that blocks the air intake and exhaust path).

Thus, in the imaging device 100, the final ball among the lenses configuring the lens group is fixed to an image sensor 132 side. In the imaging device 100 shown in FIG. 2, the final ball, i.e., the lens 123-4 is fixed to the frame 134. However, as the lenses 123-1 to 123-3 are involved in the lens barrel 122, and can be moved in a vertical direction to the image sensor 132, it is possible to adjust a focus by moving the lens barrel 122.

Also, by fixing the lens 123-4 to the frame 134, it can be configured such that the foreign matters are prevented from entering into the space 135, as described above.

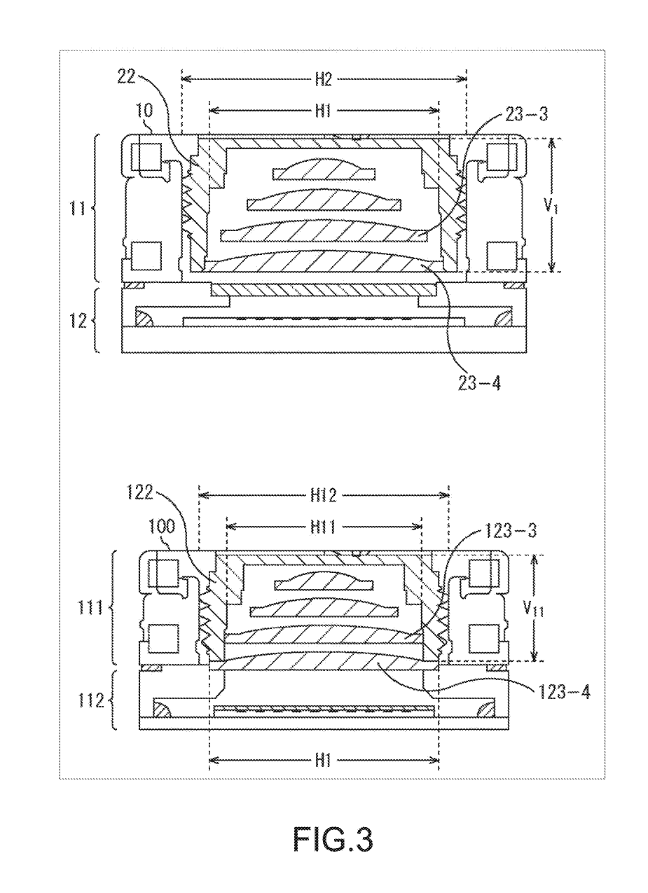

Furthermore, as described referring to FIG. 3, the imaging device 100 is downsized.

In FIG. 3, the imaging device 10 shown in FIG. 1 and the imaging device 100 shown in FIG. 2 are shown by arranging in the up-and-down direction. A length in a horizontal direction of the lens 23-4 that is the final ball of the imaging device 10 is represented by a width H1, and a length in a horizontal direction of the lens barrel 22 is represented by a width H12. A length in a horizontal direction of the lens 123-4 that is the final ball of the imaging device 100 is represented by a width H1, and a length in a horizontal direction of the lens barrel 122 is represented by a width H12.

The size of the lens 23-4 that is the final ball of the imaging device 10 and the size of the lens 123-4 that is the final ball of the imaging device 100 may be the same. Also, the size of each of lenses 23-1 to 23-3 of the imaging device 10 and the size of each of the lenses 123-1 to 123-3 of the imaging device 100 may be the same. As the size of each of the lenses 23-1 to 23-4 and the size of each of the lenses 123-1 to 123-4 are the same, and an optical system of the lens group is not downsized, there is no optical property difference between the imaging device 10 and the imaging device 100.

In the imaging device 10 shown in an upper side of FIG. 3, as the lens 23-4 is included in the lens barrel 22, the lens barrel 22 is necessary to have a size to include the lens 23-4. When the size of the lens 23-4 is the width H1, the lens barrel 22 is necessary to have the width H2 greater than the width H1.

In the imaging device 100 shown in a lower side of FIG. 3, as the lens 123-3 is included in the lens barrel 122, the lens barrel 122 is necessary to have a size to include the lens 123-3. When the size of the lens 123-3 is the width H1, the lens barrel 122 is necessary to have the width H2 greater than the width H1.

In general, the final ball among a plurality of lenses configuring the lens group is greater than other lenses. Accordingly, the lens 123-3 can be smaller than the lens 123-4 that is the final ball. That is to say, the width H11 of the lens 123-3 can be smaller than the H1 of the lens 123-4. Accordingly, the width H12 of lens barrel 122 including the lens 123-3 can be smaller than the width H2 of lens barrel 22 including the lens 23-4.

In this way, according to the imaging device 100 to which the present technology is applied, the size of the lens barrel 122 in the horizontal direction can be decreased. In other words, the diameter of the lens barrel 122 is smaller than the diameter of the lens 123-4 that is the final ball, thereby downsizing the lens barrel 122.

A length in a horizontal direction of the lens barrel 22 of the imaging device 10 is represented by a height V1, and a length in a horizontal direction of the lens barrel 122 of the imaging device 100 is represented by a height V11.

As the lens barrel 22 of the imaging device 10 includes the four lenses of the lenses 23-1 to 23-4, the height V1 is necessary to include the four lenses. In contrast, as the lens barrel 122 of the imaging device 100 includes three lenses of the lenses 123-1 to 123-3, the height V11 is only necessary to include the three lenses.

Accordingly, the height V11 of the lens barrel 122 of the imaging device 100 is lower than the height V1 of the lens barrel 22 of the imaging device 10. In other words, according to the imaging device 100 to which the present technology is applied, the size in the vertical direction of the lens barrel 22 can be decreased. Thus, the lens barrel 122 can be downsized.

In this way, the lens barrel 122 of the imaging device 100 can be smaller than the lens barrel 22 of the imaging device 10. Accordingly, the imaging device 100 including the downsized lens barrel 122 can be downsized as it is. This allows electric power to be saved as described above.

<Other Configuration of Imaging Device>

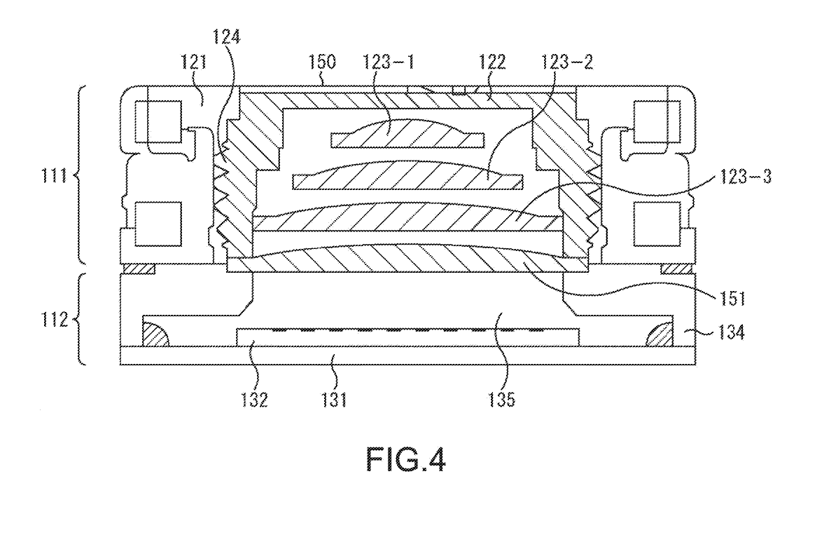

FIG. 4 is a view showing other configuration of a downsized imaging device. As an imaging device 150 shown in FIG. 4 basically has the similar configuration as to the imaging device 100 shown in FIG. 2, the components already described are denoted by the same reference numerals, and thus detailed description thereof will be hereinafter omitted.

The imaging device 150 shown in FIG. 4 has a configuration that the IRCF 133 in the imaging device 100 shown in FIG. 2 is removed. In the imaging device 150, the lens 151 that is the final ball of the lens group has a function of the IRCF 133. In other words, a surface at an image sensor 132 of the lens 151 or a surface at a lens 123-3 side of the lens 151 is provided with an infrared ray cut filter function.

For example, by forming a film for cutting infrared rays on any surface of the lens 151, the lens 151 may be provided with the function of the IRCF 133. Alternatively, a material for cutting infrared rays may be used for the material of the lens 151.

The imaging device 150 also has effects that the imaging device 100 described referring to FIG. 2 has. Specifically, it can be configured to prevent the foreign matters from entering into the space 135. Also, the lens barrel 122 can be downsized, and the size of the imaging device 150 itself can be downsized.

In addition, the lens 151 of the final ball configuring the lens group is provided with the function for cutting infrared rays, thereby omitting an infrared ray cut filter (IRCF). Thus, the number of the components configuring the imaging device 150 can be reduced. Also, it is possible to further thin the imaging device 150 to the extent of the omission of the infrared ray cut filter.

In FIG. 4, it is illustrated that the lens 151 that is the final ball is provided with the function of the infrared ray cut filter (IRCF). Instead, any of the lenses 123-1 to 123-3 other than the lens 151 may be provided with the function.

Also, as described by referring to FIG. 2, it is possible to provide the IRCF 133 above the image sensor 132. When the IRCF 133 is provided, the IRCF 133 is not limited to be positioned above the image sensor 132. Although not shown, the IRCF 133 may be positioned between the image sensor 132 and the lens 123-4 (FIG. 2), for example.

Also, it may be positioned between any lenses of the lens 123-1 to the lens 123-4. For example, it may be positioned between the lens 123-3 and the lens 123-4, or the IRCF 133 may be positioned between the lens 123-2 and the lens 123-3.

As long as a percentage of cutting is 99% or more in total in the optical system within a wavelength range from 700 nm to 1000 nm as an infrared rays cutting function, it may be provided at any position in the imaging device 100, or the lens may have the function of the IRCF like the imaging device 150.

In addition, although the lens 123-4 is included in the lower part 112 in the imaging device 100 shown in FIG. 2 and the imaging device 150 shown in FIG. 3, other lenses, i.e., the lens 123-3 may also be included in the lower part 112, and be fixed.

Furthermore, in the imaging device 100 shown in FIG. 2 and the imaging device 150 show in FIG. 3, the lens 123-4 that is the final ball among the lenses configuring the lens group is fixed, and the lenses 123-1 to 123-3 are movable in the up-and-down direction, whereby the lenses 123-1 to 123-3 are moved to execute focusing.

The lens 123-1 is also fixed, and the present technology is applicable to a structure that is commonly referred to as an inner focus. Specifically, the lens 123-1 and the lens 123-4 are fixed, and the lens 123-2 and the lens 123-3 are movable. Thus, the lens 123-2 and the lens 123-3 are moved to execute focusing.

That is to say, the present technology is applicable to a structure that fixes lenses positioned at a frontmost surface and an endmost surface among a plurality of lenses configuring the lens group, and moves lenses other than the lenses positioned at the frontmost surface and the endmost surface upon focusing.

Also, the present technology is applicable to an imaging device including a lens barrel having a structure that aligns a lens group configured of a plurality of lenses and an final ball separately while verifying an optical performance such as an MTF (Modulation Transfer Function).

Furthermore, like the imaging device 100 shown in FIG. 2 and the imaging device 150 show in FIG. 3, the lens 123-4 (lens at the endmost surface) near at an image sensor 133 side has a curved shape, which is a shape that can reflect stray light components incident on the image sensor 133 outwardly the image sensor 133. This allows ghosts and flares to be reduced, and an image quality to be improved.

<Electronic Apparatus>

The present technology is not limited to be applied to an imaging device, but whole electronic devices using the imaging device at an image capturing unit (photoelectric converting unit) including an imaging device such as a digital still camera and a video camera, a mobile terminal device having an imaging function such as a mobile phone, and a copying machine using an imaging device for an image reading unit. The imaging device may be a module configuration mounted to an electronic apparatus, i.e., a camera module.

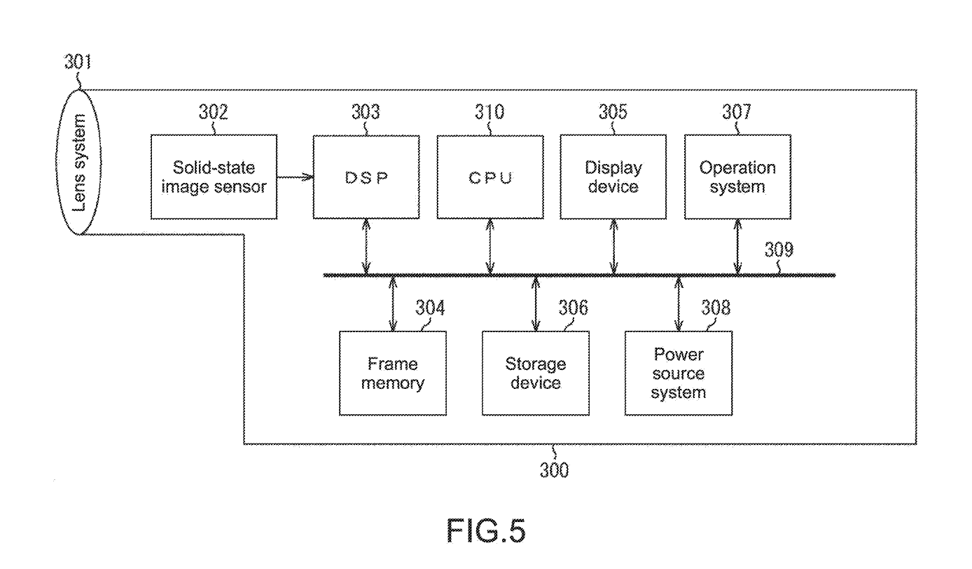

FIG. 5 is a block diagram showing an illustrative configuration of an imaging device that is an illustrative electronic apparatus according to the present disclosure. As shown in FIG. 5, An imaging device 300 according to the present disclosure includes an optical system having a lens group 301 etc., an image sensor 302, a DSP circuit 303 that is a camera signal processing unit, a frame memory 304, a display device 305, a storing device 306, an operation system 307, a power source system 308 and the like.

The DSP circuit 303, the frame memory 304, the display device 305, the storing device 306, the operation system 307, and the power source system 308 are mutually connected via a bus line 309. The CPU 310 controls each unit in the imaging device 300.

The lens group 301 takes in an incident light (image light), and forms an image on an imaging surface of the image sensor 302. The image sensor 302 converts an amount of incident light imaged on the imaging surface by the lens group 301 into an electric signal, and outputs as a pixel signal. As the image sensor 302, a solid-state image sensor according to the aforementioned embodiments can be used.

The display device 305 is configured of a panel display device such as a liquid crystal display device and an organic EL (electro luminescence) display device, and displays a video image or a still image captured by the image sensor 302. The storing device 306 stores the video image or the still image captured by the image sensor 302 into a storage medium such as a video tape and a DVD (Digital Versatile Disk).

The operation system 307 issues an operation command about a variety of functions of the imaging device under operation by a user. The power source system 308 supplies a variety of power sources that are operating power sources for the DSP circuit 303, the frame memory 304, the display device 305, the storing device 306, and the operation system 307 to supply targets, as appropriate.

The imaging device 300 is applied to a video camera, a digital still camera, and a camera module for a mobile device such as a mobile phone. In the imaging device 300, the imaging device 100 (150) according to the aforementioned embodiments as the lens group 301 and the image sensor 302 can be used.

It should be noted that the effect described here is not necessarily limitative and may be any effect described in the present disclosure.

It should be noted that the embodiments of the present technology is not limited to the above-described embodiments, and variations and modifications may be made without departing from the scope of the present technology.

The present technology may have the following configurations.

(1) An imaging device, including:

a substrate to which an image sensor is mounted;

a frame that fixes a lens; and

the lens,

the substrate, the frame, and the lens sealing the image sensor.

(2) The imaging device according to (1), including a plurality of lenses, in which the lens fixed to the frame is a lens positioned nearest to the image sensor among the plurality of lenses.

(3) The imaging device according to (1), further including:

a plurality of lenses; and

a lens barrel that holds the lenses, in which

the lenses other than the lens positioned near the image sensor among the plurality of lenses are held by the lens barrel.

(4) The imaging device according to (3), in which

a diameter of the lens barrel is smaller than a diameter of the lens fixed to the frame.

(5) The imaging device according to any one of (1) to (4), further including:

an IRCF (Infra Red Cut Filter) on the image sensor.

(6) The imaging device according to any one of (1) to (4), in which

the lens has a function to cut infrared rays.

(7) The imaging device according to any one of (1) to (4), further including:

an IRCF (Infra Red Cut Filter).

(8) The imaging device according to any one of (1) to (7), including:

a plurality of lenses, in which

the lenses other than the lenses positioned at a frontmost surface and an endmost surface among the plurality of lenses move upon focusing.

(9) An electronic apparatus, including:

an imaging device including
a substrate to which an image sensor is mounted;
a frame that fixes a lens; and
the lens,
the substrate, the frame, and the lens sealing the image sensor, and

a signal processing unit that performs signal processing to a signal output from the imaging device.

### DESCRIPTION OF SYMBOLS

100 imaging device
121 actuator
122 lens barrel
123 lens
131 substrate
132 image sensor
133 IRCF
134 frame
150 imaging device
151 lens

1. An imaging device, comprising:
a substrate to which an image sensor is mounted;
a frame that fixes a lens; and
the lens,
the substrate, the frame, and the lens sealing the image sensor.

2. The imaging device according to claim 1, comprising:
a plurality of lenses,
wherein the lens fixed to the frame is a lens positioned nearest to the image sensor among the plurality of lenses.

3. The imaging device according to claim 1, further comprising:
a plurality of lenses; and
a lens barrel that holds the lenses, wherein
the lenses other than the lens positioned near the image sensor among the plurality of lenses are held by the lens barrel.

4. The imaging device according to claim 3, wherein
a diameter of the lens barrel is smaller than a diameter of the lens fixed to the frame.

5. The imaging device according to claim 1, further comprising:
an IRCF (Infra Red Cut Filter) on the image sensor.

6. The imaging device according to claim 1, wherein
the lens has a function to cut infrared rays.

7. The imaging device according to claim 1, further comprising:
an IRCF (Infra Red Cut Filter).

8. The imaging device according to claim 1, comprising:
a plurality of lenses, wherein
the lenses other than the lenses positioned at a frontmost surface and an endmost surface among the plurality of lenses move upon focusing.

9. An electronic apparatus, comprising:
an imaging device including
a substrate to which an image sensor is mounted,
a frame that fixes a lens, and
the lens,
the substrate, the frame, and the lens sealing the image sensor; and
a signal processing unit that performs signal processing to a signal output from the imaging device.
